(19) United States
(12) Patent Application Publication
(10) Pub. No.: US 2012/0214556 A1
(43) Pub. Date: Aug. 23, 2012

(54) Method and Apparatus for Solar Cell Light Concentrator Panel

(75) Inventors: Ilkka NIEMELA, Nokia (FI); Lasse PURMA, Hameenlinna (FI); Arto MESKANEN, Nokia (FI)

(73) Assignee: Nokia Corporation

(21) Appl. No.: 13/029,442

(22) Filed: Feb. 17, 2011

(51) Int. Cl. H04W 88/02; H01L 31/052; H01L 31/18; H01L 31/0232

(52) U.S. Cl. 455/572; 136/259; 136/246; 29/890.033

(57) ABSTRACT

In accordance with an example embodiment of the present invention, an apparatus is disclosed. The apparatus includes a photovoltaic cell and a sheet shaped member. The sheet shaped member has a surface and an edge. The surface is proximate an exterior portion of the apparatus. The photovoltaic cell is at the edge of the sheet shaped member. The sheet shaped member forms a light guide configured to collect light incident on the light guide. The light guide is configured to concentrate the light at the photovoltaic cell.

### TECHNICAL FIELD

The invention relates to a solar cell light concentrator panel.

### BACKGROUND

Increase of computing power of portable devices is turning them into versatile portable computers, which can be used for multiple different purposes. Versatile components and/or features are therefore used in order to take full advantage of capabilities of mobile devices.

Additionally, consumers are increasingly conscious of environmental issues, and therefore mobile devices capable of utilizing clean energy from the sun are increasingly popular. Using solar energy to charge the battery of a mobile device also makes it possible to extend the operating time of the device in situations where grid power is not available for charging.

Accordingly, as consumers demand increased functionality from the electronic device, there is a need to provide an improved device having increased capabilities, while maintaining robust and reliable product configurations.

### SUMMARY

Various aspects of examples of the invention are set out in the claims.

According to a first aspect of the present invention, an apparatus is disclosed. The apparatus includes a photovoltaic cell and a sheet shaped member. The sheet shaped member has a surface and an edge. The surface is proximate an exterior portion of the apparatus. The photovoltaic cell is at the edge of the sheet shaped member. The sheet shaped member forms a light guide configured to collect light incident on the light guide. The light guide is configured to concentrate the light at the photovoltaic cell.

According to a second aspect of the present invention, an apparatus is disclosed. The apparatus includes a housing having a first housing section and a second housing section. The second housing section includes a device cover member. The device cover member includes a translucent element having a first portion and a second portion. The first portion is configured to receive light incident on the translucent element. The second portion is configured to be connected to a photovoltaic cell. The translucent element is configured to channel the light from the first portion to the second portion. The second portion is configured to deliver the light to the photovoltaic cell.

According to a third aspect of the present invention, a method is disclosed. A photovoltaic cell is provided at a device. A sheet shaped member is provided proximate an exterior portion of the device. The sheet shaped member includes a surface and an edge. The photovoltaic cell is at the edge of the sheet shaped member. The sheet shaped member forms a light guide configured to collect light incident on the light guide. The light guide is configured to concentrate the light at the photovoltaic cell.

### BRIEF DESCRIPTION OF THE DRAWINGS

For a more complete understanding of example embodiments of the present invention, reference is now made to the following descriptions taken in connection with the accompanying drawings in which:

FIG. 1 is a front view of an electronic device incorporating features of the invention;

FIG. 2 is a perspective view of a rear housing section of the electronic device shown in FIG. 1;

FIG. 3 is another perspective view of the rear housing section of the electronic device shown in FIG. 1;

FIG. 4 is a cross section view of the rear housing section shown in FIGS. 2, 3;

FIG. 5 is a cross section view of another exemplary housing section incorporating features of the invention;

FIG. 6 is a perspective view of another exemplary housing section incorporating features of the invention;

FIG. 7 is an exploded perspective view of the housing section shown in FIG. 6;

FIG. 8 is a perspective view of a frame section of the device incorporating features of the invention;

FIG. 9 is another perspective view of the frame section of the device incorporating features of the invention; and

FIG. 10 is a block diagram of an exemplary method of the device shown in FIG. 1.

### DETAILED DESCRIPTION OF THE DRAWINGS

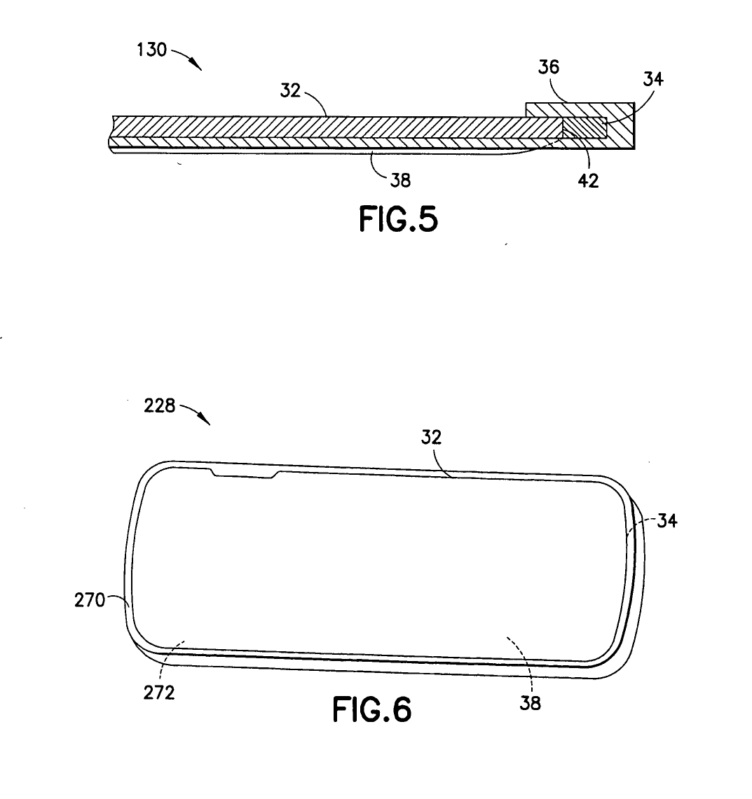

An example embodiment of the present invention and its potential advantages are understood by referring to FIGS. 1 through 10 of the drawings.

Referring to FIG. 1, there is shown a front view of an electronic device 10 incorporating features of the invention. Although the invention will be described with reference to the exemplary embodiments shown in the drawings, it should be understood that the invention can be embodied in many alternate forms of embodiments. In addition, any suitable size, shape or type of elements or materials could be used.

According to one example of the invention, the device 10 is a multi-function portable electronic device. However, in alternate embodiments, features of the various embodiments of the invention could be used in any suitable type of portable electronic device such as a mobile phone, a gaming device, a music player, a notebook computer, or a personal digital assistant, for example. In addition, as is known in the art, the device 10 can include multiple features or applications such as a camera, a music player, a game player, or an Internet browser, for example. The device 10 generally comprises a housing 12, a battery 14, a transmitter 16, a receiver 18, an antenna 20 (connected to the transmitter 16 and the receiver 18), electronic circuitry 22, such as a controller (which could include a processor, for example) and a memory for example, within the housing 12, a user input region 24 and a display 26. The display 26 could also form a user input section, such as a touch screen. It should be noted that in alternate embodiments, the device 10 can have any suitable type of features as known in the art.

According to various exemplary embodiments of the invention, the housing 12 includes a front housing section 28 and a rear housing section 30. However, in alternate embodiments any suitable number of housing sections may be provided. For example, in one example embodiment the rear housing section may form a rear cover for the device. In another example embodiment the rear housing section can include a separate battery cover. However, it should be noted that these are provided as non-limiting examples and any suitable device cover member configuration may be provided.

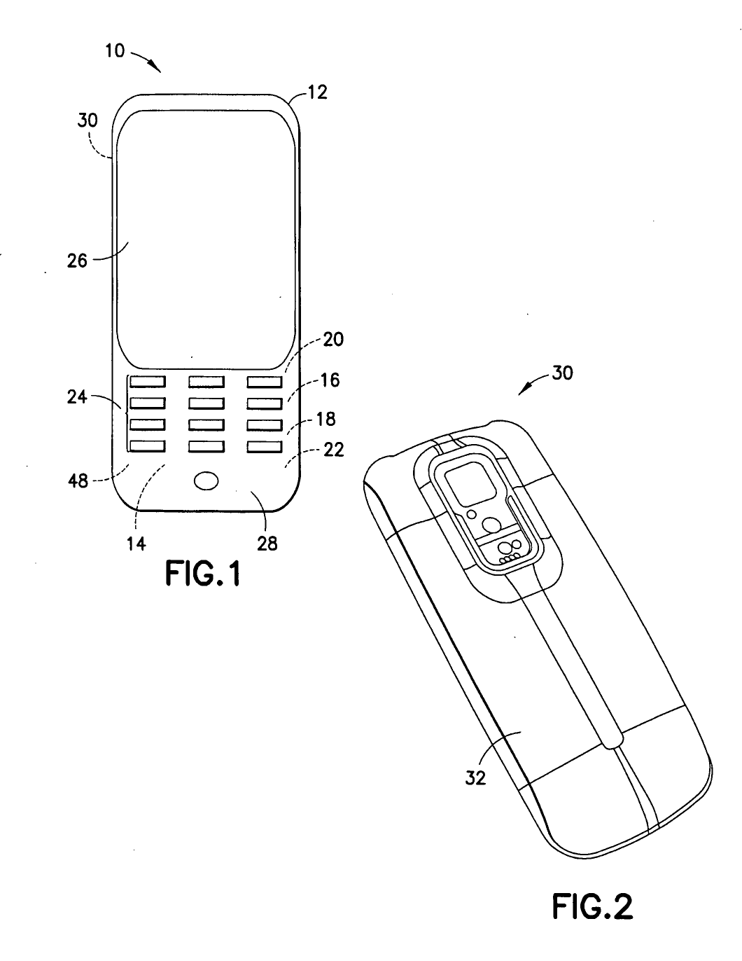

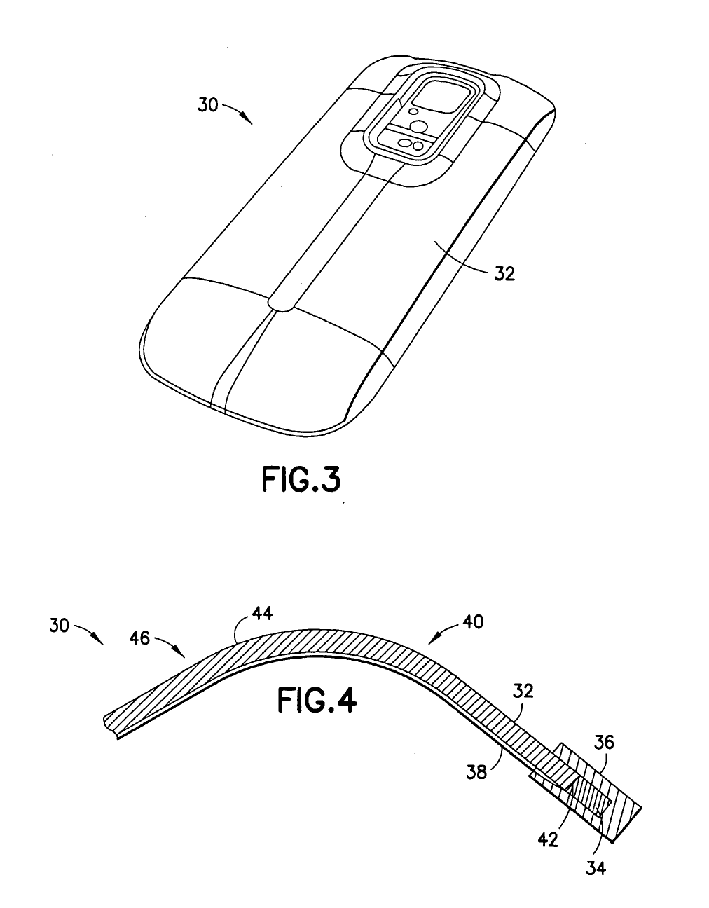

Referring now also to FIGS. 2, 3, the rear housing section 30 of the electronic device 10 is shown. According to various exemplary embodiments of the invention, there is provided a device housing section (or device cover member) having a translucent layer that works as a light guide and concentrates solar radiation into a photovoltaic cell. Referring now also to FIG. 4, there is shown a cross-section view of a portion of the rear housing section 30. According to some embodiments of the invention, the rear housing section 30 comprises a translucent element 32, a solar cell 34, a solar cell shielding member 36, and a flexible printed wiring board (PWB) 38.

The translucent element 32 comprises a general sheet shape (or a general panel/plate shape) with curved sections 40. For example, according to some embodiments of the invention, the curved sections 40 are proximate edges 42 of the translucent element 32. However, any suitable configuration may be provided. According to some embodiments of the invention, the translucent element 32 is formed as a semi-transparent device cover part that provides a light guide and works as a light concentrator. For example, the translucent element 32 is configured to collect light and concentrate it to the solar cells 34. Such a part can be created from different types of transparent or semi-transparent plastics and covered with a light concentrator coating 44, such as a coating provided by GreenSun Energy of Jerusalem, Israel, for example. However, any suitable type of light concentrator coating may be provided. According to some embodiments of the invention, the light concentrator coating may be integrated with the translucent element 32 with a molding process, such as an In-Mold Labeling (IML) process for example. However, any suitable type of molding or injection molding process may be utilized. It should further be noted that according to some other embodiments of the invention, the transparent/semi-transparent plastic material (without the coating) of the translucent element may have light concentrating properties wherein the transparent/semi-transparent plastic material forms a lightguide and is configured to collect light incident on the light guide and concentrate the light at the edges 42 of the lightguide 32.

With this configuration, for example, an exterior portion 46 of the translucent member 32 is configured to receive light incident on the exterior portion 46, and an interior portion, such as the edge 42, for example, is configured to be connected to the solar cell 34. This further provides for the translucent element 32 to be configured to channel light from the exterior portion 46 to the edge 42.

According to some embodiments of the invention, the translucent element 32 includes planar and curved sections. It should be noted that any suitable curve radius may be provided, however in some embodiments relatively large curvature radiuses may be provided in order to benefit from the light concentration effect.

The solar cell 34 comprises a solar cell receptor with relatively small dimensions. For example, the solar cell receptor 34 may be any suitable solar cell receptor such as one provided by GreenSun Energy of Jerusalem, Israel, for example. The solar cells 34 are configured to convert light into electricity. According to some embodiments of the invention the solar cell 34 is a photovoltaic cell. However, in alternate embodiments, any suitable type of solar cell may be provided.

The solar cell shielding member 36 provides a protective covering for the solar cells 34, as the solar cells may be somewhat fragile, such as in drop cases, for example. The solar cell shielding member 36 also provides a fixing point for the solar cells 34 and gives an appealing outlook for the device 10 at the solar cell area. The cell shielding member 36 may be formed from any suitable type of material such as plastic or metal, for example. Additionally, the cell shielding member 36 may be fabricated using any suitable type of method/technology.

The flexible printed wiring board (PWB) 38 provides an electricity conductor which translates electricity from the solar cells 34 to the battery 14 and charging electronics 48 (wherein the charging electronics 48 provide charging functionality, such as for charging the battery 14, for example). It should be understood that any suitable type of thin flexible PWB technology, such as those used as standard solutions on mobile phones for signal and electricity transfer, may be provided. It should further be noted that in some embodiments, the flexible printed wiring board could be replaced with any other suitable configuration comprising alternative technologies to manufacture electrical conductors, such as configurations wherein electrical conductors are formed directly on the solar concentrator substrate using, for example. Additionally, some exemplary embodiments of invention can include various molded interconnect device techniques such as selective electroplating, electrically conductive ink, and/or plasma coating, for example. However, these are merely provided as non-limiting examples and it should be understood that any suitable configuration may be provided.

It should be noted that although the embodiments above have been described with the translucent element (or sheet shaped member) having general flat/planar sections and curved sections proximate the edges, any suitable shape or configuration may be provided. For example, referring now also to Fig. illustrating another exemplary embodiment of the invention, a rear housing section 130 is shown wherein the translucent element 132 has a general flat shape without the curved sections proximate the edges 42.

According to some embodiments of the invention, one advantageous location for the translucent element having solar concentrator capabilities is the device back cover (or rear housing section). For example, device back covers generally comprise a large area that can be used for the light contractor. Some other embodiments of the invention may provide for just a battery cover portion of the device back cover to include the light concentrator implementation. However, in other alternate embodiments, lightguides and solar cells that convert light into the electricity can be integrated into any suitable type device cover.

It should be noted that although the embodiments have been described above in connection with a rear housing section/cover, alternate embodiments may provide the translucent element, the solar cell, the solar cell shielding member, and the flexible printed wiring board (PWB) at a front housing section.

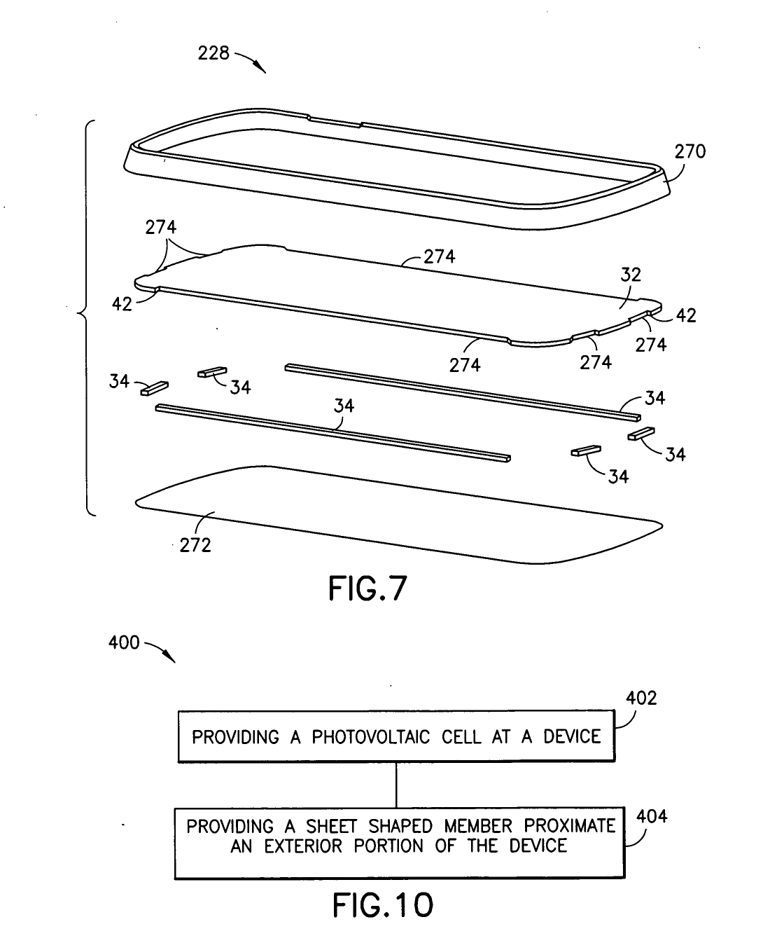

Referring now also to FIG. 6, there is shown an alternate embodiment of a front housing section 228 incorporating features of the invention. The front housing section 228 is similar to the front housing section 28. Also, similar to the rear housing section 30, 130, the front housing section 228 comprises a translucent element 32, solar cells 34, and a flexible printed wiring board (PWB) 38. However, according to some embodiments of the invention, the housing section 228 further comprises a bezel 270 and a support member 272 (see FIG. 7).

Similar to the embodiments above, the translucent element 32 comprises a transparent/semi-transparent sheet which forms a lightguide. Also similar to the embodiments above, the solar cells 34 are at edges of the translucent element 32. However, in this embodiment the lightguide 32 comprises edge cutout sections 274 sized and shaped to receive the solar cells 34. Additionally, the in this embodiment, the edges 42 of translucent element 32 and the solar cells 34 are surrounded by the bezel 270 and the support member 272. The bezel 270 and the support member 272 act as a solar cell shielding member and fixedly dispose the solar cells at the cutout sections 274. According to some embodiments of the invention, the support member 272 comprises a thin white paper sheet (or tape). However, in other embodiments the support member can comprise any suitable configuration.

It should be noted that although the housing section 228 has been described above in connection with a front housing section/cover, alternate embodiments may provide the housing section 228 as a rear housing section.

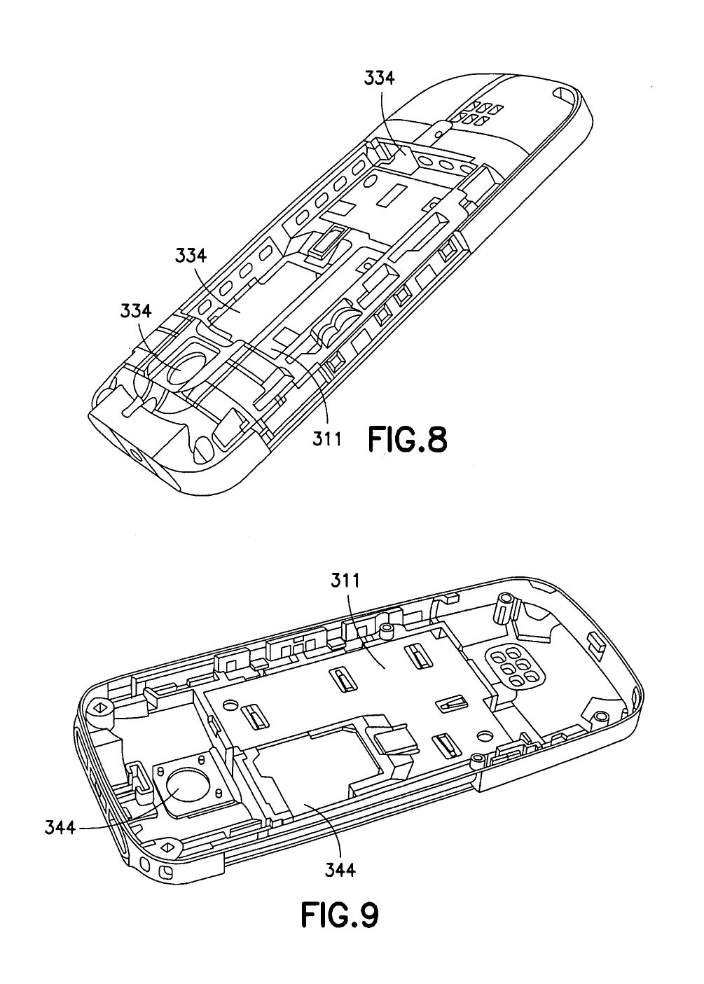

It should further be noted that although the embodiments have been described above in connection with providing the solar cells at exterior housing sections of the device, some alternate embodiments can provide solar cell(s) 334 at a frame section 311 of the device (see FIGS. 8, 9). For example, the solar cells 344 may be integrated into sheet metal portions of the frame 311 of the device. However, in alternate embodiments, the solar cells 344 may be provided at any other suitable interior section (such as a phone printed wiring board, for example) of the device.

FIG. 10 illustrates a method 400. The method 400 includes providing a photovoltaic cell at a device (at block 402). Providing a sheet shaped member proximate an exterior portion of the device, wherein the sheet shaped member comprises a surface and an edge, wherein the photovoltaic cell is at the edge of the sheet shaped member, wherein the sheet shaped member forms a light guide configured to collect light incident on the light guide, and wherein the light guide is configured to concentrate the light at the photovoltaic cell (at block 404). It should be noted that the illustration of a particular order of the blocks does not necessarily imply that there is a required or preferred order for the blocks and the order and arrangement of the blocks may be varied. Furthermore it may be possible for some blocks to be omitted.

Technical effects of any one or more of the exemplary embodiments provide for using a light concentrator coating, or light concentrator material, at the device cover member (or device cover part). With the use of this light concentrator coating/material, device radio frequency (RF), or visual decoration possibilities, are not limited. Also use of a light concentrator material makes possible to decrease the size of solar cell, which can decrease the cost of solar cell application.

While various exemplary embodiments of the invention have been described above in connection with FIGS. 1-10, one skilled in the art will appreciate that embodiments of the invention are not necessarily so limited, and that any suitable type of transparent or semi-transparent cover part that works as a lightguide and is connected to a solar cell may be provided.

Technical effects of any one or more of the exemplary embodiments provide using a light guide as a concentrator of solar radiation for a photovoltaic (PV) cell installed in a mobile device which provides significant advantages when compared to conventional configurations which use concentrator arrangements to boost output of the cells, as these conventional arrangements can be problematic because they require the device to track movement of the sun across the sky, and generally do not utilize diffuse light efficiently.

Without in any way limiting the scope, interpretation, or application of the claims appearing below, a technical effect of one or more of the example embodiments disclosed herein is increasing the integrated solar cell efficiency in the electronic device. Another technical effect of one or more of the example embodiments disclosed herein is decreasing the solar cell interference to the device antenna radiator. Another technical effect of one or more of the example embodiments disclosed herein is improving the solar cell application robustness (as the solar cells are integrated inside the device mechanics). Another technical effect of one or more of the example embodiments disclosed herein is providing the ability to use the solar cell in an environment where light is diffused (as the solar cell does not need direct sun light). Another technical effect of one or more of the example embodiments disclosed herein is decreasing the cost of the device solar charging system. Another technical effect of one or more of the example embodiments disclosed herein is integrating the solar cell visual look at the device and providing for the use different colors and a 3D surface on the integrated solar cell application.

Technical effects of any one or more of the exemplary embodiments provide for the integration of a solar cell light concentrator panel into a device cover which provides significant advantages when compared to conventional configurations which use solar cells integrated in device covers (or various other conventional concentrators for solar panels used in fixed installations). For example, with various exemplary embodiments of the invention the size of the solar cell can be decreased so that it can be implemented into the device mechanics. Additionally, with the decrease of the solar cell size decrease generating power.

Another technical effect of one or more of the example embodiments disclosed herein is providing for more design freedom for the solar cell implementation into the mobile device. Another technical effect of one or more of the example embodiments disclosed herein is decreasing the cost of solar charging system by using smaller solar panels. Another technical effect of one or more of the example embodiments disclosed herein is provide for a solar cell and charging system which can be used without having direct sunlight, as the device can be charged at the room light (such as, with diffused light, for example). Another technical effect of one or more of the example embodiments disclosed herein is providing improved configurations for integrating such solar cells and lightguides into mobile phones/devices.

It should be understood that components of the invention can be operationally coupled or connected and that any number or combination of intervening elements can exist (including no intervening elements). The connections can be direct or indirect and additionally there can merely be a functional relationship between components.

As used in this application, the term ‘circuitry’ refers to all of the following: (a)hardware-only circuit implementations (such as implementations in only analog and/or digital circuitry) and (b) to combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions) and (c) to circuits, such as a microprocessor(s) or a portion of a microprocessor(s), that require software or firmware for operation, even if the software or firmware is not physically present.

This definition of ‘circuitry’ applies to all uses of this term in this application, including in any claims. As a further example, as used in this application, the term “circuitry” would also cover an implementation of merely a processor (or multiple processors) or portion of a processor and its (or their) accompanying software and/or firmware. The term “circuitry” would also cover, for example and if applicable to the particular claim element, a baseband integrated circuit or applications processor integrated circuit for a mobile phone or a similar integrated circuit in server, a cellular network device, or other network device.

Embodiments of the present invention may be implemented in software, hardware, application logic or a combination of software, hardware and application logic. The software, application logic and/or hardware may reside on the device, or a server. If desired, part of the software, application logic and/or hardware may reside on the device, and part of the software, application logic and/or hardware may reside on the server. In an example embodiment, the application logic, software or an instruction set is maintained on any one of various conventional computer-readable media. In the context of this document, a “computer-readable medium” may be any media or means that can contain, store, communicate, propagate or transport the instructions for use by or in connection with an instruction execution system, apparatus, or device, such as a computer, with one example of a computer described and depicted in FIG. 1. A computer-readable medium may comprise a computer-readable storage medium that may be any media or means that can contain or store the instructions for use by or in connection with an instruction execution system, apparatus, or device, such as a computer.

If desired, the different functions discussed herein may be performed in a different order and/or concurrently with each other. Furthermore, if desired, one or more of the above-described functions may be optional or may be combined.

Below are provided further descriptions of various non-limiting, exemplary embodiments. Various aspects of one or more exemplary embodiments may be practiced in conjunction with one or more other aspects or exemplary embodiments. That is, the exemplary embodiments of the invention, such as those described immediately below, may be implemented, practiced or utilized in any combination (for example, any combination that is suitable, practicable and/or feasible) and are not limited only to those combinations described herein and/or included in the appended claims.

In one exemplary embodiment, an apparatus comprising a photovoltaic cell and a sheet shaped member is disclosed. The sheet shaped member having a surface and an edge, wherein the surface is proximate an exterior portion of the apparatus, wherein the photovoltaic cell is at the edge of the sheet shaped member, wherein the sheet shaped member forms a light guide configured to collect light incident on the light guide, and wherein the light guide is configured to concentrate the light at the photovoltaic cell.

The apparatus as above, wherein the sheet shaped member forms at least a portion of a device cover member.

The apparatus as above, wherein light guide comprises a translucent material.

The apparatus as above, wherein the light guide is configured to concentrate the light at the edge.

The apparatus as above, wherein the sheet shaped member is connected to the photovoltaic cell at the edge.

The apparatus as above, wherein the sheet shaped member comprises a curved section.

The apparatus as above, wherein the apparatus further comprises a flexible printed wiring board connected to the photovoltaic cell.

The apparatus as above, wherein the apparatus further comprises a shield member surrounding a portion of the photovoltaic cell.

The apparatus as above, wherein the apparatus further comprises a bezel surrounding the photovoltaic cell and the sheet shaped member.

In another exemplary embodiment, an apparatus comprising a housing having a first housing section and a second housing section is disclosed. The second housing section comprises a device cover member, wherein the device cover member comprises a translucent element having a first portion and a second portion, wherein the first portion is configured to receive light incident on the translucent element, wherein the second portion is configured to be connected to a photovoltaic cell, wherein the translucent element is configured to channel the light from the first portion to the second portion, and wherein the second portion is configured to deliver the light to the photovoltaic cell.

The apparatus as above, wherein the translucent element is a sheet shaped member.

The apparatus as above, wherein the first portion is a surface, and wherein the second portion is an edge.

The apparatus as above, wherein the translucent element comprises a curved section.

The apparatus as above, wherein the device cover member further comprises a flexible printed wiring board connected to the photovoltaic cell and a shield member surrounding a portion of the photovoltaic cell.

The apparatus as above, wherein the second housing section further comprises another photovoltaic cell, wherein the another photovoltaic cell is at a third portion of the translucent element.

The apparatus as above, wherein the apparatus comprises a mobile phone, wherein the first housing section is a front cover member, and wherein the device cover member is a rear cover member.

Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations and modifications which may be made without departing from the scope of the present invention as defined in the appended claims.

1. An apparatus, comprising:
a photovoltaic cell; and
a sheet shaped member having a surface and an edge, wherein the surface is proximate an exterior portion of the apparatus, wherein the photovoltaic cell is at the edge of the sheet shaped member, wherein the sheet shaped member forms a light guide configured to collect light incident on the light guide, and wherein the light guide is configured to concentrate the light at the photovoltaic cell.

2. An apparatus as in claim 1 wherein the sheet shaped member forms at least a portion of a device cover member.

3. An apparatus as in claim 1 wherein the light guide comprises a translucent material.

4. An apparatus as in claim 1 wherein the light guide is configured to concentrate the light at the edge.

5. An apparatus as in claim 1 wherein the sheet shaped member is connected to the photovoltaic cell at the edge.

6. An apparatus as in claim 1 wherein the sheet shaped member comprises a curved section.

7. An apparatus as in claim 1 wherein the apparatus further comprises a flexible printed wiring board connected to the photovoltaic cell.

8. An apparatus as in claim 1 wherein the apparatus further comprises a shield member surrounding a portion of the photovoltaic cell.

9. An apparatus as in claim 1 wherein the apparatus further comprises a bezel surrounding the photovoltaic cell and the sheet shaped member.

10. An apparatus comprising a housing having a first housing section and a second housing section, wherein the second housing section comprises a device cover member, wherein the device cover member comprises a translucent element having a first portion and a second portion, wherein the first portion is configured to receive light incident on the translucent element, wherein the second portion is configured to be connected to a photovoltaic cell, wherein the translucent element is configured to channel the light from the first portion to the second portion, and wherein the second portion is configured to deliver the light to the photovoltaic cell.

11. An apparatus as in claim 10 wherein the translucent element is a sheet shaped member.

12. An apparatus as in claim 10 wherein the first portion is a surface, and wherein the second portion is an edge.

13. An apparatus as in claim 10 wherein the translucent element comprises a curved section.

14. An apparatus as in claim 10 wherein the device cover member further comprises a flexible printed wiring board connected to the photovoltaic cell and a shield member surrounding a portion of the photovoltaic cell.

15. An apparatus as in claim 10 wherein the second housing section further comprises another photovoltaic cell, wherein the another photovoltaic cell is at a third portion of the translucent element.

16. An apparatus as in claim 10 wherein the apparatus comprises a mobile phone, wherein the first housing section is a front cover member, and wherein the device cover member is a rear cover member.

17. A method, comprising:
providing a photovoltaic cell at a device; and
providing a sheet shaped member proximate an exterior portion of the device, wherein the sheet shaped member comprises a surface and an edge, wherein the photovoltaic cell is at the edge of the sheet shaped member, wherein the sheet shaped member forms a light guide configured to collect light incident on the light guide, and wherein the light guide is configured to concentrate the light at the photovoltaic cell.

18. A method as in claim 17 wherein the sheet shaped member forms at least a portion of a device cover member.

19. A method as in claim 17 wherein at least a portion of the sheet shaped member comprises a translucent material.

20. A method as in claim 17 wherein the sheet shaped member comprises a curved section.
